(19) United States
(12) Patent Application Publication
(10) Pub. No.: US 2019/0334084 A1
(43) Pub. Date: Oct. 31, 2019

(54) RESISTIVE RANDOM ACCESS MEMORY STRUCTURE AND MANUFACTURING METHOD THEREOF

(71) Applicant: Winbond Electronics Corp., Taichung City (TW)

(72) Inventors: Tzu-Ming OU YANG, Tainan City (TW); Ling-Chun TSENG, Taichung City (TW); Yen-De LEE, Taichung City (TW)

(21) Appl. No.: 16/398,385

(22) Filed: Apr. 30, 2019

(30) Foreign Application Priority Data
Apr. 30, 2018 (TW) 107114685

(51) Int. Cl. H01L 45/00

(52) U.S. Cl. CPC H01L 45/1253; H01L 45/1675; H01L 45/1625; H01L 45/1616

(57) ABSTRACT

A resistive random access memory (RRAM) structure and its manufacturing method are provided. The RRAM structure includes a bottom electrode layer formed on a substrate, a resistance switching layer formed on the bottom electrode layer, and a top electrode layer formed on the resistance switching layer. The top electrode layer forms a recess. The RRAM structure also includes a liner formed on a sidewall of the bottom electrode layer, a sidewall of the resistance switching layer, and a sidewall of the top electrode layer. The liner includes a hydrogen gas barrier material. The RRAM structure also includes an insulating layer formed on the liner. A material of the insulating layer is different from the hydrogen gas barrier material.

### CROSS REFERENCE TO RELATED APPLICATIONS

This Application claims priority of Taiwan Patent Application No. 107114685, filed on Apr. 30, 2018, the entirety of which is incorporated by reference herein.

### BACKGROUND

### Field of the Disclosure

The present disclosure relates to a memory device, and in particular relates to a resistive random access memory structure and a method for manufacturing the resistive random access memory structure.

### Description of the Related Art

Resistive random access memory (RRAM) has advantages, such as having a simple structure, a small area, a low operating voltage, a fast operating speed, a long memory time, capable for multi-bit storage, and low power consumption. Hence RRAM has great potential to replace the current flash memory for being the mainstream of non-volatile memory in the next generation.

A conventional RRAM includes a plurality of memory cells, each of which includes a bottom electrode layer, a resistance switching layer, and a top electrode layer. In the step of patterning the top electrode layer or in the subsequent process thereafter, the sidewall of the top electrode layer may easily be damaged, and even the sidewall of the top electrode layer is recessed. As the number and depth of the recesses increase, the electrical resistance value of the RRAM in the low resistance state (LRS) becomes high, and even cannot operate normally and fails. In addition, the number and depth of the recesses of these memory cells are uncontrollable, so that there is an uncontrollable variation in the electrical resistance values of these memory cells. As a result, the reliability and yield of the RRAM are reduced.

In addition, the etching gas (for example, boron trichloride, chlorine gas, oxygen gas, and/or nitrogen gas) used in the step of patterning the top electrode layer is easily reacted with the material of the top electrode layer (for example, titanium), and a layer of by-products (such as TiO₂, TiON, etc.) may be formed on the sidewall of the top electrode layer. In the subsequent process, the by-product layer may swell by absorbing moisture in the environment, and it may peel off from the top electrode layer. Alternatively, in the subsequent process, the by-product layer may also be stressed and peeled off from the top electrode layer. After the by-product layer peels off, it is possible to contact another memory cell, thereby causing a short circuit between adjacent memory cells. In order to avoid the short circuit, a conventional method of fabricating a RRAM requires performing a wet etching step to completely remove the above-mentioned by-product layer. However, performing the wet etching step may excessively etch the sidewalls of the top electrode layer, thereby causing the sidewalls of the top electrode layer being recessed deeper.

For the memory industry, in order to further improve the reliability and product yield of the RRAM, there is still a need to improve the RRAM and its process.

### BRIEF SUMMARY

The disclosure provides a resistive random access memory structure. The resistive random access memory structure includes a bottom electrode layer formed on a substrate, a first insulating layer formed between the bottom electrode layer and the substrate, a resistance switching layer formed on the bottom electrode layer, and a top electrode layer formed on the resistance switching layer. The top electrode layer forms a recess. The resistive random access memory structure also includes a liner formed on a sidewall of the bottom electrode layer, a sidewall of the resistance switching layer, and a sidewall of the top electrode layer. The liner includes a hydrogen gas barrier material. The resistive random access memory structure also includes a second insulating layer formed on the liner. The material of the second insulating layer is different from the hydrogen gas barrier material. A part of the liner is located between the first insulating layer and the second insulating layer, and a bottom surface of the part of the liner is lower than a bottom surface of the bottom electrode layer.

The disclosure also provides a method for manufacturing a resistive random access memory structure. The method includes forming a first insulating layer on a substrate, forming a bottom electrode layer on the first insulating layer; forming a resistance switching layer on the bottom electrode layer, and forming a sacrificial layer on the resistance switching layer, wherein a material of the sacrificial layer is different from a material of the resistance switching layer. The method also includes patterning the sacrificial layer, the resistance switching layer, and the bottom electrode layer. The method also includes forming a liner to conformally cover the sacrificial layer, the resistance switching layer, the bottom electrode layer, and the substrate. The liner includes a hydrogen gas barrier material. The method also includes forming a second insulating layer on the liner. The material of the second insulating layer is different from the hydrogen gas barrier material. The method also includes removing the liner on the sacrificial layer to expose a top surface of the sacrificial layer. The method also includes removing the sacrificial layer to expose a top surface of the resistance switching layer. The method also includes conformally forming a top electrode layer on the resistance switching layer. The top electrode layer forms a recess.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1G show cross-sectional views showing various steps of manufacturing a resistive random access memory structure in accordance with some embodiments; and

FIG. 2 shows the cross-sectional view of a resistive random access memory structure in accordance with other embodiments.

### DETAILED DESCRIPTION

The present disclosure is best understood from the following detailed description when read with the accompanying figures. It should be noted that, in accordance with the standard practice in the industry, various features are not drawn to scale. In fact, the relative dimensions of the various features may be arbitrarily increased or reduced for clarity of discussion. In addition, the present disclosure may repeat reference numerals and/or letters in the various examples. This repetition is for the purpose of simplicity and clarity and does not in itself dictate a relationship between the various embodiments and/or configurations discussed.

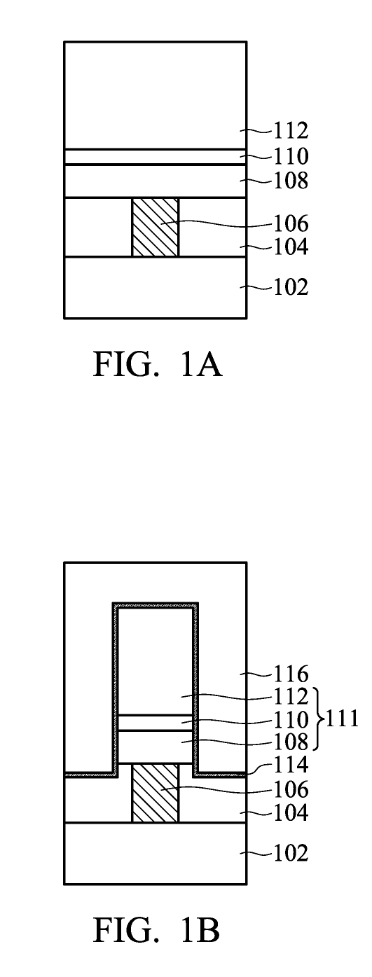

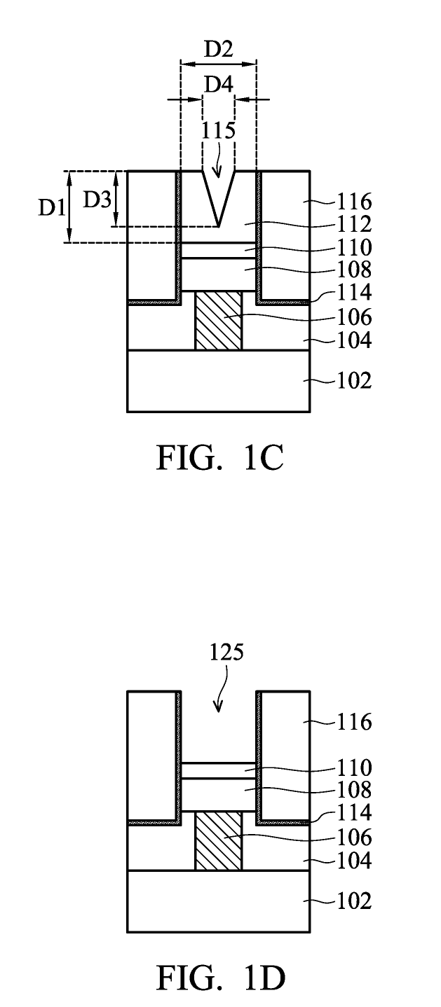

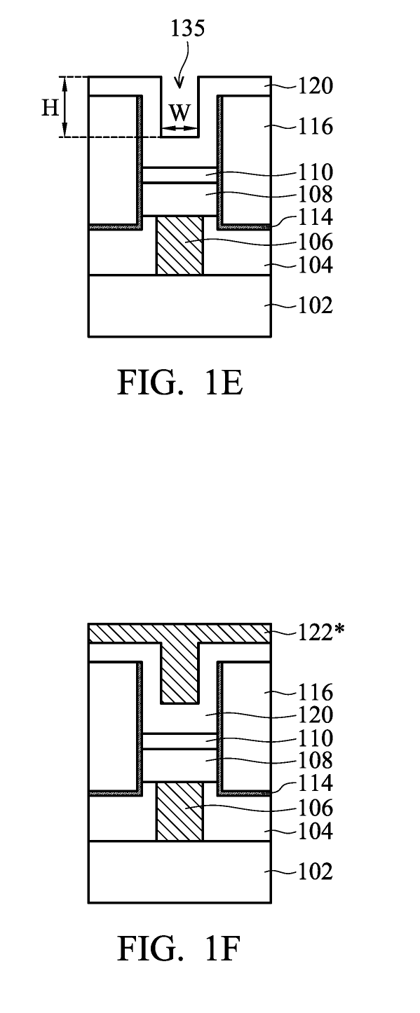

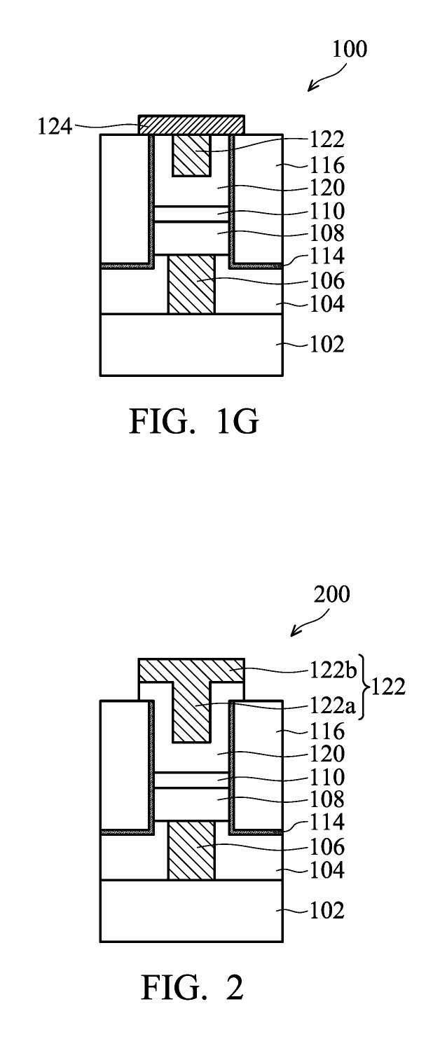

FIGS. 1A-1G show cross-sectional views showing various steps of manufacturing a resistive random access memory structure in accordance with some embodiments.

Referring to FIG. 1A, the first insulating layer 104 is formed on the substrate 102. The substrate 102 may include a bulk semiconductor substrate (for example, a silicon substrate), a compound semiconductor substrate (for example, a IIIA-VA group semiconductor substrate), a silicon on insulator (SOI) substrate, and so on. The substrate 102 may be a doped or an undoped semiconductor substrate. In some embodiments, the substrate 102 is a silicon substrate. The first insulating layer 104 may include a suitable insulating material, such as an oxide or an oxynitride. In some embodiments, the material of the first insulating layer 104 is silicon dioxide.

Then, the first insulating layer 104 is patterned to form a via hole. Then, a metal material is filled into the via hole, and the excess metal material on the first insulating layer 104 is removed by a planarization process (for example, a chemical mechanical polishing process) to form the metal plug 106 in the first insulating layer 104. The metal plug 106 may include tungsten, aluminum, other suitable metals, or a combination thereof. In some embodiments, the material of the metal plug 106 is tungsten.

Then, the bottom electrode layer 108 is formed on the first insulating layer 104, and is electrically connected to the metal plug 106. The bottom electrode layer 108 may include a suitable conductive material, such as titanium, tantalum, titanium nitride, tantalum nitride, and so on. The bottom electrode layer 108 may be a single layer structure formed by a single material or a multilayer structure formed by different materials. More specifically, in some embodiments, the bottom electrode layer 108 is a single layer structure formed by titanium nitride. The bottom electrode layer 108 may be formed by a physical vapor deposition process, a chemical vapor deposition process, or another suitable deposition process.

Then, the resistance switching layer 110 is formed on the bottom electrode layer 108. The resistance switching layer 110 may be switched to a different resistance state by applying a voltage to the bottom electrode layer 108 and the subsequently formed top electrode layer 120. When a formation voltage or a write voltage is applied to the resistive random access memory structure, the oxygen anions in the resistance switching layer 110 move into the subsequently formed top electrode layer 120, and the equivalent positive-charged oxygen vacancies remained in the resistance switching layer 110 form conductive filaments. Therefore, the resistance switching layer 110 is switched from the high resistance state (HRS) to the LRS. Conversely, when an erase voltage is applied, the oxygen anions in the top electrode layer 120 return to the resistance switching layer 110, and combine with the equivalent positive-charged oxygen vacancies in the resistance switching layer 110. Therefore, the above-mentioned conductive filaments disappear. As a result, the resistance switching layer 110 is switched from the LRS to the HRS.

The resistance switching layer 110 may include a transition metal oxide, such as tantalum oxide (Ta₂O₅), hafnium oxide (HfO₂), or zirconium oxide (ZrO₂). In some embodiments, the material of the resistance switching layer 110 is hafnium oxide. The resistance switching layer 110 may be formed by a suitable process, for example, a sputtering process, an atomic layer deposition process, a chemical vapor deposition process, an evaporation process, or another suitable deposition process.

Then, the sacrificial layer 112 is formed on the resistance switching layer 110. The sacrificial layer 112 can prevent the sidewalls of the subsequently formed top electrode layer 120 from being etched, and therefore, the reliability and yield of the RRAM can be significantly improved. The material of the sacrificial layer 112 is different from the material of the resistance switching layer 110. In some embodiments, the material of the sacrificial layer 112 is also different from the material of the bottom electrode layer 108. In some embodiments, the material of the sacrificial layer 112 is also different from the material of the first insulating layer 104. The sacrificial layer 112 may include monocrystalline silicon, polycrystalline silicon, amorphous silicon, or a combination thereof. In some embodiments, the material of the sacrificial layer 112 is polycrystalline silicon. The sacrificial layer 112 may be formed by a chemical vapor deposition process or other suitable deposition processes.

Referring to FIG. 1B, the sacrificial layer 112, the resistance switching layer 110, and the bottom electrode layer 108 are patterned by a first etching process, so as to form a stacked structure 111 including the patterned sacrificial layer 112, the patterned resistance switching layer 110 and the patterned bottom electrode layer 108. The stacked structure 111 is formed at the position corresponding to the metal plug 106. The first etching process may be an anisotropic etching process. In some embodiments, the first etching process is a dry etching process using plasma. Furthermore, in this embodiment, in order to ensure that the stacked structures 111 can be electrically insulated from one to another, the first etching process may be performed to a position deeper than the bottom surface of the bottom electrode layer 108. In other words, the first etching process may remove a portion of the first insulating layer 104. In other embodiments, the first etching process may proceed to a position being level with the bottom surface of the bottom electrode layer 108.

Then, the liner 114 is formed to conformally cover the stacked structure 111 and the substrate 102. The material of the liner 114 is different from the material of the sacrificial layer 112. The liner 114 can prevent the hydrogen gas generated in the subsequent process from entering the stacked structure 111 or entering other components of the substrate 102 via the stacked structure 111. Therefore, the degradation or failure of the RRAM can be reduced. As a result, the reliability and yield of the RRAM can be further improved. More specifically, in the subsequent process of forming the second insulating layer 116, the precursor of the second insulating layer 116 may generate hydrogen gas as a by-product. If the liner 114 is not formed, the generated hydrogen gas may enter the stacked structure 111 or enter other components of the substrate 102 via the stacked structure 111. The oxides in the stacked structure 111 (for example, the oxides in the resistance switching layer 110) may be reduced by the hydrogen gas, and oxygen or water may be produced. As a result, the characteristics of the resistance switching layer 110 will be changed, and the intended function of the resistance switching layer 110 cannot be achieved. Furthermore, the water can also cause the degradation or failure of the device. Similarly, if the hydrogen gas enters other components of the substrate 102, it may also cause the degradation or failure of these components.

The liner 114 has a good hydrogen gas barrier ability. Furthermore, in order to avoid reducing the performance of the RRAM, the liner 114 does not chemically react with the layers which are in contact with the liner 114. The liner 114 may include a hydrogen gas barrier material, such as a metal oxide, a metal nitride, a metal nitride, or a combination thereof. In some embodiments, the material of the liner 114 is aluminum oxide (Al₂O₃). In order to block the hydrogen gas effectively and allow the liner 114 to be removed efficiently in subsequent processes, the thickness of the liner 114 is preferably in a range of 5-50 nm. In some embodiments, in order to control the thickness of the liner 114 to the nanometer scale precisely, the liner 114 is formed by an atomic layer deposition process or other suitable deposition processes. In this embodiment, the liner 114 is aluminum oxide having a thickness of 10 nm and is formed by an atomic layer deposition process.

Then, the second insulating layer 116 is formed on the liner 114. In order to improve the insulating property and to reduce the costs, the material of the second insulating layer 116 may be different from the hydrogen gas barrier material of the liner 114. The material and formation method of the second insulating layer 116 may be the same as or similar to the material and formation method of the first insulating layer 104, and the details will not be repeated here. In this embodiment, the material of the second insulating layer 116 is silicon dioxide.

Referring to FIG. 1C, the liner 114 and the second insulating layer 116 overlying the sacrificial layer 112 are removed by a planarization process (for example, a chemical mechanical polishing process), so as to expose the top surface of the sacrificial layer 112. Then, a portion of the sacrificial layer 112 is removed by a second etching process, and the first opening 115 is formed in the sacrificial layer 112. In order to form the first opening 115 having a relatively high aspect ratio, the second etching process may be an anisotropic etching process. In some embodiments, the second etching process is a dry etching process using plasma. Furthermore, in this embodiment, in order to ensure that the resistance switching layer 110 is not damaged, the second etching process may proceed to a position shallower than the bottom surface of the sacrificial layer 112. In other words, the first opening 115 does not expose the top surface of the resistance switching layer 110 after the second etching process.

Referring to FIG. 1C, the sacrificial layer 112 is completely removed by the third etching process to form the second opening 125 exposing the top surface of the resistance switching layer 110. The third etching process may be an isotropic etching process. In some embodiments, the third etching process is a wet etching process using an etching solution.

Referring to FIG. 1E, the top electrode layer 120 is conformally formed on the resistance switching layer 110, and a recess 135 is defined by the contour of the top electrode layer 120. The top electrode layer 120 may include a conductive material, such as titanium, tantalum, titanium nitride, tantalum nitride, and so on. The top electrode layer 120 may be a single layer structure formed by a single material or a multilayer structure formed by different materials. In some embodiments, the top electrode layer 120 is a single layer structure formed by titanium. In other embodiments, the top electrode layer 120 is a dual-layer structure formed by titanium nitride and titanium thereon. The top electrode layer 120 may be formed by using a physical vapor deposition process, a chemical vapor deposition process, or other suitable deposition processes.

Referring to FIG. 1F, the first conductive material 122* is deposited on the top electrode layer 120 and filled into the recess 135. The first conductive material 122* may include a suitable conductive material, such as tungsten, aluminum, another suitable metal, or a combination thereof. The material and formation method of the first conductive material 122* may be the same as or similar to the material and formation method of the metal plug 106, and the details will not be repeated here.

Referring to FIG. 1G a portion of the first conductive material 122* and a portion of the top electrode layer 120 are removed by a planarization process to form the contact plug 122 in the recess 135. In the planarization process, the first conductive material 122* and the top electrode layer 120 overlying the second insulating layer 116 and the liner 114 are removed, so that the top surface of the second insulating layer 116 and the top surface of the liner 114 are exposed. Therefore, after the planarization process, the top surface of the contact plug 122, the top surface of the top electrode layer 120, and the top surface of the second insulating layer 116 are coplanar with the top surface of the liner 114. In such an embodiment, no plasma is used in the step of forming the contact plug 122. Therefore, the second insulating layer 116 will not come into contact with any plasma, and it is advantageous for improving the reliability and yield of the RRAM.

The second conductive material is deposited on the contact plug 122 and the top electrode layer 120. Then, the second conductive material is patterned to form the conductive line 124 on the contact plug 122 and the top electrode layer 120. The second conductive material may include a suitable conductive material, such as silver, copper, aluminum, another suitable metal, or a combination thereof. In some embodiments, the second conductive material is an aluminum copper alloy. The conductive line 124 may be formed by an atomic layer deposition process or other suitable deposition processes.

In this embodiment, the material of the conductive line 124 is different from the first conductive material 122*. More specifically, the gap filling ability of the first conductive material 122* is better than the gap filling ability of the second conductive material. As such, even if the recess 135 has a large aspect ratio (for example, an aspect ratio that is greater than 5), there are no voids or holes in the contact plug 122. In order to reduce the electrical resistance value of the RRAM, the conductivity of the second conductive material may be better than the conductivity of the first conductive material 122*.

In some embodiments of the present disclosure, the top electrode layer 120 has not been formed when the first etching process is performed. Therefore, the top electrode layer 120 is not damaged by the first etching process. Furthermore, as showed in FIG. 1E, the top electrode layer 120 is formed in the second opening 125 defined by the patterned sacrificial layer 112, and the sidewalls of the top electrode layer 120 does not need to be defined by a patterning process. Moreover, the sidewalls of the top electrode layer 120 is protected by the liner 114 and the second insulating layer 116, so that the sidewalls of the top electrode layer 120 will not be damaged during the subsequent processes. Therefore, the sidewalls of the top electrode layer 120 of the present invention are smooth. As a result, the reliability and yield of the RRAM can be significantly improved.

In the present invention, the sacrificial layer 112 needs to be completely removed to expose the top surface of the resistance switching layer 110. If only an anisotropic etching process (for example, a dry etching process) is performed, it will be difficult to remove the bottom corners of the sacrificial layer 112. Particularly in the case where the width of the sacrificial layer 112 is gradually narrowed upward, in order to completely remove the sacrificial layer 112, it is necessary to extend the duration of the etching process. As a result, the resistance switching layer 110 may be severely damaged by the etching process. On the other hand, referring to FIG. 1C, the etching depth of the sacrificial layer 112 in the vertical direction and the etching width in the horizontal direction are D1 and D2, respectively. If only an isotropic etching process (for example, a wet etching process) is performed, in the case where the aspect ratio (i.e., D1/D2) of the sacrificial layer 112 is large (for example, the aspect ratio is greater than 2), in order to the remove the bottom of the sacrificial layer 112, it is necessary to extend the duration of the etching process. As a result, the etching solution may penetrate into the underlying layers (for example, the bottom electrode layer 108) along the sidewalls of the sacrificial layer 112. Therefore, it may result in the degradation or failure of the RRAM.

In order to completely remove the sacrificial layer 112, in some embodiments of the present disclosure, the first opening 115 is first formed in the sacrificial layer 112 by using the anisotropic second etching process, as shown in FIG. 1C. Then, the sacrificial layer 112 is completely removed by using the isotropic third etching process to expose the top surface of the resistance switching layer 110, and the second opening 125 is formed, as shown in FIG. 1D.

More specifically, the depth and width of the first opening 115 are D3 and D4, respectively. Because both D3 and D4 are smaller than D1, it is possible to prevent the resistance switching layer 110 from being severely damaged by an excessive anisotropic etching process. Furthermore, because the first opening 115 has been formed before the third etching process, the bottom of the sacrificial layer 112 is more easily removed in the third etching process, and the duration of the third etching process is shortened. Therefore, the etching solution will not penetrate into the underlying layers along the sidewalls of the sacrificial layer 112.

In addition, the third etching process has a high etching selectivity for the sacrificial layer 112 and the resistance switching layer 110, and the resistance switching layer 110 can be prevented from being damaged during the third etching process. As a result, the top surface of the resistance switching layer 110 is flat. Therefore, the yield of the RRAM is improved. In some embodiments, the ratio R1/R2 of the etching rate R1 of the sacrificial layer 112 to the etching rate R2 of the resistance switching layer 110 is 10-100 during the third etch process.

In addition, because the third etching process has a high etching selectivity for the sacrificial layer 112 and the liner 114, the liner 114 can be prevented from being damaged during the third etching process, and the above-mentioned problem relative to the penetration of the etching solution can be further solved or avoided. In some embodiments, the ratio R1/R3 of the etching rate R1 of the sacrificial layer 112 to the etching rate R3 of the liner layer 114 is 5-100 during the third etching process.

Referring to FIG. 1G the resistive random access memory structure 100 is provided in some embodiments of the present disclosure. The resistive random access memory structure 100 includes the first insulating layer 104, the bottom electrode layer 108, the resistance switching layer 110, the liner 114, the second insulating layer 116, and the top electrode layer 120 sequentially formed on the substrate 102. The metal plug 106 is formed in the first insulating layer 104 and is electrically connected to the bottom electrode layer 108. The liner 114 is formed on the sidewalls of the bottom electrode layer 108, the sidewalls of the resistance switching layer 110, and the sidewalls of the top electrode layer 120, and the liner 114 includes the hydrogen gas barrier material. The second insulating layer 116 is formed on the liner 114, and the material of the second insulating layer 116 is different from the hydrogen gas barrier material of the liner 114. The top electrode layer 120 is formed on the resistance switching layer 110, and the top electrode layer 120 forms the recess 135 (shown in FIG. 1E). Furthermore, the resistive random access memory structure 100 may further include the contact plug 122 and the conductive line 124. The contact plug 122 is formed in the recess 135, and the top surface of the contact plug 122 is coplanar with the top surface of the top electrode layer 120. The conductive line 124 is formed on the contact plug 122 and the top electrode layer 120. In some embodiments, the second conductive material for forming the conductive line 124 is different from the first conductive material 122* for forming the contact plug 122.

Referring to FIG. 1E, the recess 135 has a depth H and a width W, and has an aspect ratio H/W. If the aspect ratio H/W of the recess 135 is too large, it is difficult to fill the first conductive material 122* into the recess 135, and there may be voids or holes in the formed contact plug 122. As a result, the reliability and yield of the resistive random access memory structure 100 will be reduced. Therefore, in some embodiments, the recess 135 has an aspect ratio H/W in a range of 0.1-10.

FIG. 2 shows the cross-sectional view of a resistive random access memory structure 200 in accordance with other embodiments. The same elements as those in FIG. 1G are denoted by the same reference numerals. For the sake of simplicity of explanation, the elements and their formation methods which are the same as those in FIG. 1G are not repeated here. The difference between FIG. 2 and FIG. 1G is as follows.

In this embodiment, the recess 135 has a smaller aspect ratio H/W (for example, the aspect ratio H/W is less than 5). Therefore, the conductive material having a moderate gap filling ability and conductivity may be selected to be the first conductive material 122*. In this embodiment, after forming the structure shown in FIG. 1F, the first conductive material 122* and the top electrode layer 120 are not planarized, and the first conductive material 122* and the top electrode layer 120 are patterned simultaneously by an anisotropic etching process. Thereby, the surface of the top electrode layer 120 is higher than the surface of the second insulating layer 116, and the top electrode layer 120 covers a portion of the second insulating layer 116. In this embodiment, the contact plug 122a and the conductive line 122b are made of the same material, and there is no interface formed by different materials between the contact plug 122a and the conductive line 122b. Therefore, for a single resistive random access memory structure 200, there is no performance degradation due to the interface defects. For a plurality of resistive random access memory structures, there is no unevenness in electrical resistance value due to the interface defects. Therefore, the reliability of the resistive random access memory structure 200 is good. Furthermore, in such an embodiment, the step of planarizing and the step of depositing the second conductive material may be omitted. Therefore, the process can be simplified and the time and cost required for production can be reduced.

In conclusion, according to the resistive random access memory structure and the manufacturing method thereof provided by the embodiments of the present disclosure, the sidewalls of the top electrode layer are not recessed, thereby improving the reliability and yield of the resistance random access memory. In one embodiment of the present disclosure, the hydrogen gas generated in the subsequent process can be blocked by the liner which completely covers the resistance switching layer, the bottom electrode layer and the substrate, thereby reducing the degradation or failure of the resistance random access memory. By disposing the sacrificial layer and subsequently completely removing the sacrificial layer, the second opening defined after the sacrificial layer is removed has a higher aspect ratio, which is advantageous for reducing the resistance of the top electrode layer 120 which is subsequent conformally formed in the second opening, and is also advantageous for increasing the area of the top electrode layer that is protected by the liner. In addition, the material of the sacrificial layer is different from the material of the resistive transition layer, thereby avoiding the problem of uneven surface of the resistance switching layer that is exposed by the completely removing the sacrificial layer. In one embodiment of the present disclosure, an anisotropic etching process is first performed to form the first opening in the sacrificial layer, and then the sacrificial layer is completely removed by performing an isotropic etching process. As a result, the time required to remove the sacrificial layer can be significantly shortened, and the resistance switching layer and the liner can be prevented from being damaged in the step of removing the sacrificial layer. Therefore, the problem relative to the penetration of the etching solution can be solved or avoided. In one embodiment of the present disclosure, by using the same material to make the contact plugs and conductive lines, the process can be simplified, and the time and cost required for production can be reduced.

Although the disclosure has been described by way of example and in terms of the preferred embodiments, it should be understood that various modifications and similar arrangements (as would be apparent to those skilled in the art) can be made herein without departing from the spirit and scope of the disclosure as defined by the appended claims.

What is claimed is:

1. A resistive random access memory structure, comprising:
a bottom electrode layer formed on a substrate;
a first insulating layer formed between the bottom electrode layer and the substrate;
a resistance switching layer formed on the bottom electrode layer;
a top electrode layer formed on the resistance switching layer, wherein the top electrode layer forms a recess;
a liner formed on a sidewall of the bottom electrode layer, a sidewall of the resistance switching layer, and a sidewall of the top electrode layer, wherein the liner comprises a hydrogen gas barrier material; and
a second insulating layer formed on the liner, wherein a material of the second insulating layer is different from the hydrogen gas barrier material,
wherein a part of the liner is located between the first insulating layer and the second insulating layer, and a bottom surface of the part of the liner is lower than a bottom surface of the bottom electrode layer.

2. The resistive random access memory structure as claimed in claim 1, wherein the hydrogen gas barrier material is a metal oxide, a metal nitride, a metal oxynitride, or a combination thereof.

3. The resistive random access memory structure as claimed in claim 1, wherein the liner has a thickness in a range of 5-50 nm.

4. The resistive random access memory structure as claimed in claim 1, wherein the recess has an aspect ratio in a range of 0.1-10.

5. The resistive random access memory structure as claimed in claim 1, further comprising:
a contact plug formed in the recess, wherein a top surface of the contact plug is coplanar with a top surface of the top electrode layer; and
a conductive line formed on the contact plug and the top electrode layer.

6. The resistive random access memory structure as claimed in claim 5, wherein the contact plug and the conductive line are made of the same material.

7. A method for manufacturing a resistive random access memory structure, comprising:
forming a first insulating layer on a substrate;
forming a bottom electrode layer on the first insulating layer;
forming a resistance switching layer on the bottom electrode layer;
forming a sacrificial layer on the resistance switching layer, wherein a material of the sacrificial layer is different from a material of the resistance switching layer;
patterning the sacrificial layer, the resistance switching layer, and the bottom electrode layer;
forming a liner to conformally cover the sacrificial layer, the resistance switching layer, the bottom electrode layer, and the substrate, wherein the liner comprises a hydrogen gas barrier material;
forming a second insulating layer on the liner, wherein a material of the second insulating layer is different from the hydrogen gas barrier material;
removing the liner on the sacrificial layer to expose a top surface of the sacrificial layer;
removing the sacrificial layer to expose a top surface of the resistance switching layer; and
conformally forming a top electrode layer on the resistance switching layer, wherein the top electrode layer forms a recess.

8. The method for manufacturing the resistive random access memory structure as claimed in claim 7, wherein removing the sacrificial layer comprises:
performing an anisotropic etching process to remove a portion of the sacrificial layer and to form a first opening in the sacrificial layer; and
performing an isotropic etching process to completely remove the sacrificial layer and to form a second opening, wherein the second opening exposes the top surface of the resistance switching layer.

9. The method for manufacturing the resistive random access memory structure as claimed in claim 8, wherein after performing the anisotropic etching process, the first opening does not expose the top surface of the resistance switching layer.

10. The method for manufacturing the resistive random access memory structure as claimed in claim 8, wherein during the isotropic etching process, a ratio of an etching rate of the sacrificial layer to an etching rate of the resistance switching layer is 10-100.

11. The method for manufacturing the resistive random access memory structure as claimed in claim 8, wherein during the isotropic etching process, a ratio of the etching rate of the sacrificial layer to an etching rate of the liner is 5-100.

12. The method for manufacturing the resistive random access memory structure as claimed in claim 7, further comprising:
depositing a first conductive material on the top electrode layer and filling the first conductive material into the recess;
performing a planarization process to remove a portion of the first conductive material and a portion of the top electrode layer and to form a contact plug in the recess, wherein a top surface of the contact plug is coplanar with a top surface of the top electrode layer;
depositing a second conductive material on the contact plug and the top electrode layer; and
performing a patterning process to remove a portion of the second conductive material and to form a conductive line on the contact plug and the top electrode layer.

13. The method for manufacturing the resistive random access memory structure as claimed in claim 7, wherein the material of the sacrificial layer is different from a material of the bottom electrode layer and a material of the first insulating layer.

14. The method for manufacturing the resistive random access memory structure as claimed in claim 7, wherein the material of the sacrificial layer includes monocrystalline silicon, polycrystalline silicon, amorphous silicon, or a combination thereof.

15. The method for manufacturing the resistive random access memory structure as claimed in claim 7, wherein a part of the liner is located between the first insulating layer and the second insulating layer, and a bottom surface of the part of the liner is lower than a bottom surface of the bottom electrode layer.
